(19) United States
(12) Patent Application Publication
(10) Pub. No.: US 2014/0049255 A1
(43) Pub. Date: Feb. 20, 2014

(54) CORELESS CURRENT SENSOR STRUCTURE, CORELESS CURRENT SENSOR, AND CURRENT DETECTION METHOD

(71) Applicant: Shinji Kitamoto, Utsunomiya-shi (JP)

(72) Inventor: Shinji Kitamoto, Utsunomiya-shi (JP)

(73) Assignee: HONDA MOTOR CO., LTD., Tokyo (JP)

(21) Appl. No.: 14/111,955

(22) PCT Filed: Apr. 2, 2012
(86) PCT No.: PCT/JP2012/058923

§ 371 Date: Oct. 15, 2013

(30) Foreign Application Priority Data
May 20, 2011 (JP) 2011-113887

(51) Int. Cl. G01R 19/00

(52) U.S. Cl. CPC G01R 19/00
USPC 324/244

(57) ABSTRACT

In coreless current sensors of a coreless current sensor structure, and in a current detection method employed in the coreless current sensor structure, a coil-like portion that surrounds the outer circumference of a conductor, such as a shield plate, is formed of a connecting line connected to a terminal of a magnetic detection element.

### TECHNICAL FIELD

The present invention relates to a coreless current sensor structure, a coreless current sensor, and a current detecting method.

### BACKGROUND ART

There is known a coreless current sensor, which is a current sensor that does not contain a magnetic flux collector core. See, Japanese Laid-Open Patent Publication No. 2010-045874 (hereinafter referred to as “JP2010-045874A”). According to JP2010-045874A, a coreless current sensor 40 is used to control an inverter 41, which controls the output power of a three-phase AC motor 39. More specifically, in order to eliminate phase delays and gain errors contained in output voltages Vuv1, Vvw1 due to residual magnetic fluxes that are produced by a shield plate 53 of the coreless current sensor 40, the output voltages Vuv1, Vvw1 are corrected, and the inverter 41 is controlled based on the corrected output voltages Vuv1, Vvw1 together with command values that are input from an external source (see Abstract).

The output voltages Vuv1, Vvw1 are corrected using a map 5 (see, FIGS. 2(a) through 2(d)), which defines a relationship between command values id1, iq1 and rotational speeds ω of the rotor of the motor 39 and corrective values (gain corrective values A1, B1 and phase corrective values A2, B2) (see paragraphs [0030] through [0038]). Alternatively, the output voltages Vuv1, Vvw1 are corrected using a map 8 (FIG. 6), which defines a relationship between present positions θ[°] of the motor 39 and the corrective values (see paragraphs [0043] through [0045]).

### SUMMARY OF INVENTION

According to JP2010-045874A, as described above, maps of corrective values depending on rotational speeds ω and positions θ are used in order to reduce adverse effects (phase delays and gain errors contained in the output voltages Vuv1, Vvw1) of magnetic fluxes produced by the shield plate 53. Consequently, unless maps of the corrective values are kept, the output voltages Vuv1, Vvw1 cannot be corrected, and it is necessary to provide a sufficient memory capacity and to acquire data in advance, which imposes quite a high load.

The present invention has been made in view of the above problems. It is an object of the present invention to provide a coreless current sensor structure, a coreless current sensor, and a current detecting method, which are capable of preventing a reduction (phase delay) in response due to magnetic fluxes with a simple arrangement.

According to the present invention, there is provided a coreless current sensor structure comprising a magnetic detecting device for detecting a magnetic flux produced from a current path and converting the detected magnetic flux into a voltage, a shield plate disposed around the magnetic detecting device for blocking an external magnetic flux toward the magnetic detecting device, wherein an output voltage converted from a detected magnetic flux by the magnetic detecting device is converted into a current in order to detect a current flowing through the current path, and a connection line connected to terminals of the magnetic detecting device and including a coiled portion surrounding the shield plate, wherein the current is calculated based on a voltage across the magnetic detecting device.

According to the present invention, the connection line connected to the terminals of the magnetic detecting device includes the coiled portion that surrounds the shield plate. When the coiled portion generates a counter-electromotive force, which depends on a change in the magnetic flux applied to the shield plate, the generated counter-electromotive force is added to the output voltage of the magnetic detecting device.

If the coiled portion is disposed around the shield plate so as to produce the counter-electromotive force in order to compensate for a response delay in the output voltage from the magnetic detecting device, which is caused with respect to a change in the current flowing through the current path due to a delay of a change in the magnetic flux on the shield plate with respect to the change in the current, then the response delay in the output voltage can be compensated for by the counter-electromotive force. As a result, the response delay in the output voltage, i.e. a response reduction due to the magnetic flux (phase delay), can be compensated for with a simple arrangement.

Alternatively, if the coiled portion is disposed around the shield plate in order to increase the response delay in the output voltage through use of the counter-electromotive force, then the response delay in the output voltage can be increased when necessary.

The connection line, which includes the coiled portion, may further include an output line on which voltage changes depending on the voltage conversion, and the coiled portion may be coiled counterclockwise around a first specific region of the shield plate from a side of the output line proximate the magnetic detecting device and toward an output end of the output line, as the first specific region of the shield plate is viewed in a direction of the magnetic flux at the first specific region, when the magnetic detecting device outputs a positive voltage based on the generated magnetic flux produced from the current path.

The connection line may further include a ground line, and the coiled portion may be coiled clockwise around a second specific region of the shield plate from a side of the ground line proximate the magnetic detecting device and toward an output end of the ground line, as the second specific region of the shield plate is viewed in a direction of the magnetic flux at the second specific region, when the magnetic detecting device outputs a positive voltage based on the generated magnetic flux produced from the current path.

According to the present invention, there also is provided a coreless current sensor comprising a magnetic detecting device for detecting a magnetic flux produced from a current path and converting the detected magnetic flux into a voltage, a conductor disposed around the magnetic detecting device, and a wire for outputting an output voltage from the magnetic detecting device to an external circuit, the wire including a coiled portion disposed around the conductor, wherein the conductor is placed in a position in which the conductor generates an eddy current due to a magnetic flux produced from the current path, thereby causing a delay of a change in the magnetic flux detected by the magnetic detecting device with respect to a change in a current flowing through the current path, and the coiled portion of the wire is disposed such that a response delay in the output voltage from the magnetic detecting device, which is caused with respect to the change that occurs in the current flowing through the current path due to a delay of a change in the magnetic flux with respect to the change in the current, is compensated for by a counter-electromotive force generated in the coiled portion in a direction to oppose the change in the magnetic flux applied to the conductor.

According to the present invention, even if a response delay in the output voltage from the magnetic detecting device is caused with respect to a change in the current flowing through the current path due to a delay of a change in the magnetic flux on the conductor with respect to the change in the current, the response delay is compensated for by the counter-electromotive force generated in the coiled portion. Therefore, a phase deviation (response delay) can be prevented with a simple arrangement.

According to the present invention, there also is provided a current detecting method to be carried out using a coreless current sensor including a magnetic detecting device for detecting a magnetic flux produced from a current path and converting the detected magnetic flux into a voltage, a conductor disposed around the magnetic detecting device, and a wire for outputting an output voltage from the magnetic detecting device to an external circuit, the wire including a coiled portion disposed around the conductor, comprising the steps of placing the conductor in a position in which the conductor generates an eddy current due to a magnetic flux produced from the current path, thereby causing a delay of a change in the magnetic flux detected by the magnetic detecting device with respect to a change in a current flowing through the current path, generating a counter-electromotive force in the coiled portion in a direction to oppose the change in the magnetic flux applied to the conductor, and compensating for a phase deviation between the waveform of the current flowing through the current path and the waveform of an output from the magnetic detecting device by using the counter-electromotive force for the conductor, the phase deviation being caused due to the delay of the change in the magnetic flux with respect to the change in the current.

### BRIEF DESCRIPTION OF DRAWINGS

FIG. 1 is a block diagram of an electric vehicle incorporating a plurality of coreless current sensors according to an embodiment of the present invention;

FIG. 2A is a plan view showing schematically the structure of each of the coreless current sensors according to the embodiment;

FIG. 2B is a cross-sectional view taken along line IIB-IIB of FIG. 2A, showing the structure of the coreless current sensor;

FIG. 3A is a plan view of a coreless current sensor according to a comparative example, showing the manner in which a positive current flows through a bus bar;

FIG. 3B is a cross-sectional view taken along line IIIB-IIIB of FIG. 3A;

FIG. 4 is a view showing the manner in which an eddy current is generated in a shield plate shown in FIGS. 3A and 3B;

FIG. 5 is a diagram showing the relationship between a current flowing through the bus bar (bus bar current), an output voltage from a magnetic detecting device (device voltage), a counter-electromotive force generated for the shield plate, and an error caused by a response delay of the device voltage with respect to the bus bar current in the comparative example;

FIG. 6A is a plan view of the coreless current sensor according to the comparative example, showing the manner in which a negative current flows through the bus bar;

FIG. 6B is a cross-sectional view taken along line VIB-VIB of FIG. 6A;

FIG. 7 is a view showing the manner in which an eddy current is generated in the shield plate shown in FIGS. 6A and 6B;

FIG. 8A is a plan view of the coreless current sensor according to the present embodiment, showing the manner in which a positive current flows through a bus bar;

FIG. 8B is a cross-sectional view taken along line VIIIB-VIIIB of FIG. 8A;

FIG. 9 is a diagram showing the relationship between the bus bar current and the device voltage according to the embodiment;

FIG. 10A is a plan view of the coreless current sensor according to the present embodiment, showing the manner in which a negative current flows through the bus bar;

FIG. 10B is a cross-sectional view taken along line XB-XB of FIG. 10A;

FIG. 11 is a diagram showing by way of example the relationship between numbers of turns of a turn wire around the shield plate and phase deviations of a corrected device voltage;

FIG. 12 is a plan view showing schematically the structure of a first modification of the coreless current sensor shown in FIG. 2A;

FIG. 13 is a plan view showing schematically the structure of a second modification of the coreless current sensor shown in FIG. 2A; and

FIG. 14 is a plan view showing schematically the structure of a third modification of the coreless current sensor shown in FIG. 2A.

### DESCRIPTION OF EMBODIMENTS

### 1. Embodiment

### [1-1. Arrangement of Electric Vehicle 10]

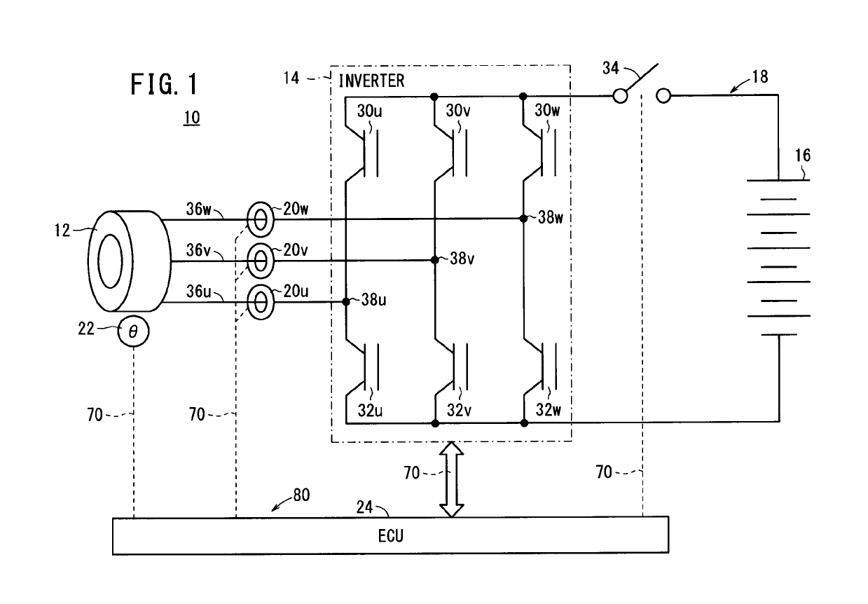

FIG. 1 is a block diagram of an electric vehicle 10 (hereinafter referred to as a “vehicle 10”) incorporating therein plural coreless current sensors 20u, 20v, 20w according to an embodiment of the present invention. The coreless current sensors 20u, 20v, 20w also are referred to as “current sensors 20u, 20v, 20w”, and are collectively referred to as “coreless current sensors 20” or simply “current sensors 20”.

In addition to the coreless current sensors 20, the vehicle includes a propulsive motor 12 (hereinafter referred to as a “motor 12”), an inverter 14, a battery 16, a power supply circuit 18, a resolver 22, and an electronic control unit 24 (hereinafter referred to as an “ECU 24”).

### [1-2. Drive System]

The motor 12, which comprises a three-phase AC brushless motor, generates a drive force F [N] (or a torque [N·m]) for the vehicle 10 based on electric power supplied from the battery 16 through the power supply circuit 18 and the inverter 14. The motor 12 also outputs electric power (regenerated electric power Preg) [W] generated in a regenerative mode to the battery 16 and a non-illustrated auxiliary, in order to charge the battery 16 and to energize the auxiliary.

The inverter 14, which is of a three-phase full-bridge configuration, converts direct current from the battery 16 into a three-phase alternating current and supplies the three-phase alternating current to the motor 12. The inverter 14 also supplies the battery 16 and the auxiliary with direct current, which is converted from an alternating current generated by the motor 12 in a regenerative mode. The inverter 14 includes upper switching elements 30u, 30v, 30w (hereinafter collectively referred to as “upper switching elements 30”) and lower switching elements 32u, 32v, 32w (hereinafter collectively referred to as “lower switching elements 32”), which are turned on and off according to a predetermined sequence by drive signals from the ECU 24 in order to rotate the three-phase AC motor 12. The inverter 14 also includes inverse-parallel diodes, which are associated respectively with the upper switching elements 30 and the lower switching elements 32. The inverse-parallel diodes are omitted from illustration in FIG. 1.

The inverter 14 may have the same structural and operational details as those disclosed in JP2010-045874A, for example.

### [1-3. Electric Power System]

The battery 16, which serves as an energy storage device including a plurality of battery cells, may comprise a lithium ion secondary battery, a nickel hydrogen battery, or a capacitor, for example. According to the present embodiment, the battery 16 comprises a lithium ion secondary battery. A DC/DC converter, not shown, may be connected between the inverter 14 and the battery 16, for stepping up or stepping down an output voltage from the battery 16 or an output voltage from the motor 12.

The power supply circuit 18 includes a relay switch 34 and bus bars 36u, 36v, 36w (hereinafter collectively referred to as “bus bars 36”).

The relay switch 34 comprises a normally open ON/OFF switch for use during normal operation (power mode or regenerative mode) of the vehicle 10. The relay switch 34 is connected between the inverter 14 and the positive terminal of the battery 16.

The bus bars 36u, 36v, 36w comprise copper wires in the form of plates interconnecting the motor 12 and junctions 38u, 38v, 38w between the upper switching elements 30 and the lower switching elements 32. As described above, the upper switching elements 30 and the lower switching elements 32 of the inverter 14 are turned on and off according to a predetermined sequence in order to rotate the three-phase AC motor 12. At this time, the directions of the currents that flow through the bus bars 36 are successively reversed.

### [1-4. Coreless Current Sensor 20]

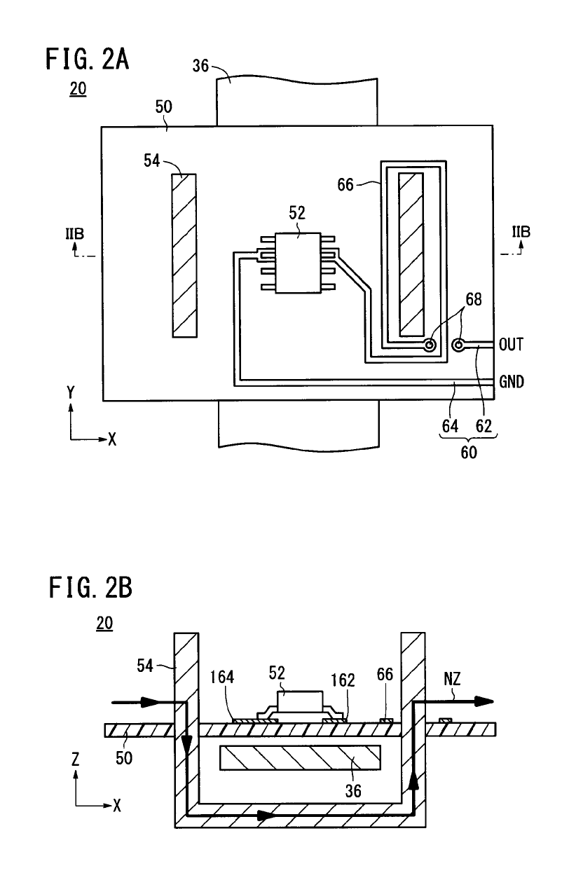

FIG. 2A is a plan view showing schematically the structure of each of the coreless current sensors 20 according to the present embodiment, and FIG. 2B is a cross-sectional view taken along line IIB-IIB of FIG. 2A, showing the structure of the coreless current sensor 20.

As shown in FIGS. 2A and 2B, the current sensor 20 includes a printed circuit board 50 disposed parallel to the bus bar 36, a magnetic detecting device 52 mounted on the printed circuit board 50, and a shield plate 54. The shield plate 54 has a lower surface parallel to the bus bar 36, and left and right surfaces that lie perpendicularly to the lower surface of the shield plate 54.

The magnetic detecting device 52 detects a magnetic flux φ1 generated by the bus bar 36 and converts the detected magnetic flux φ1 into a voltage. In other words, the magnetic detecting device 52 outputs a voltage (hereinafter referred to as a “device voltage Ve”), which is dependent on the magnetic flux φ1. Since the magnetic flux φ1 is proportional to the current flowing through the bus bar 36 (hereinafter referred to as a “bus bar current Ib”) [A], the device voltage Ve represents the bus bar current Ib. The output voltage (device voltage Ve) from the magnetic detecting device 52 is output to the ECU 24 through a printed wire 60 (connection line) that is printed on the printed circuit board 50. The magnetic detecting device 52 may comprise, for example, a Hall device, a magnetoresistance device, or a Hall IC (Integrated Circuit) in the form of an amplifier circuit combined with a Hall device.

The shield plate 54 serves to prevent disturbance noise from being applied to the magnetic detecting device 52. The shield plate 54 surrounds the bus bar 36 in three directions (downward, leftward, and rightward directions as shown in FIG. 2B). The shield plate 54 is made of a magnetically permeable material such as Permalloy or the like. As shown in FIG. 2B, when a disturbance noise NZ is generated in the direction of the magnetic detecting device 52, the disturbance noise NZ passes through the shield plate 54 but does not reach the magnetic detecting device 52. Therefore, the shield plate 54 is effective to protect the magnetic detecting device 52 from the disturbance noise NZ.

As shown in FIG. 2A, the printed wire 60 includes an output line 62 and a ground line 64. The output line 62 and the ground line 64 are connected to terminals of the magnetic detecting device 52 and to input terminals of the ECU 24.

According to the present embodiment, the output line 62 includes a turn wire 66 (coiled portion) in the form of a coil that extends around the shield plate 54. The turn wire 66 is effective to improve the output response of the current sensor 20, to be described in detail later. The printed circuit board 50 is of a double-layer structure including through holes 68, which keeps any overlapping portions of the turn wire 66 isolated and out of electric contact with each other.

### [1-5. Resolver 22]

The resolver 22 detects an electric angle θ, which is a rotation angle of an unillustrated output shaft or outer rotor of the motor 12, and outputs it to the ECU 24.

### [1-6. ECU 24]

The ECU 24 controls various components of the vehicle 10 through signal lines 70 (see FIG. 1). The ECU 24 includes non-illustrated input and output parts, an operation part, and a memory part. According to the present embodiment, the ECU 24 converts output voltages (device voltages Ve) from the current sensors 20 from analog voltages into digital voltages, so that the ECU 24 can process the digital voltages as current values (bus bar currents Ib). Stated otherwise, the current sensors 20 and the ECU 24 operate jointly to make up a coreless current sensor unit 80 (coreless current sensor structure). In FIG. 1, the signal lines 70 that interconnect the inverter 14 and the ECU 24 are shown in simplified form, however, the signal lines 70 actually interconnect the ECU 24 with the gates of the upper switching elements 30u, 30v, 30w and the lower switching elements 32u, 32v, 32w.

### 2. Operations and Advantages of the Turn Wire 66

### [2-1. In the Absence of the Turn Wire 66]

In order to explain the operations and advantages of the turn wire 66 according to the present embodiment, initially, operations in the absence of the turn wire 66 will be described below. When the inverter 14 is energized, directions of the currents that flow through the bus bars 36 are switched in succession, as described above.

### (2-1-1. When the Bus Bar Current Ib Flows in a Positive Direction)

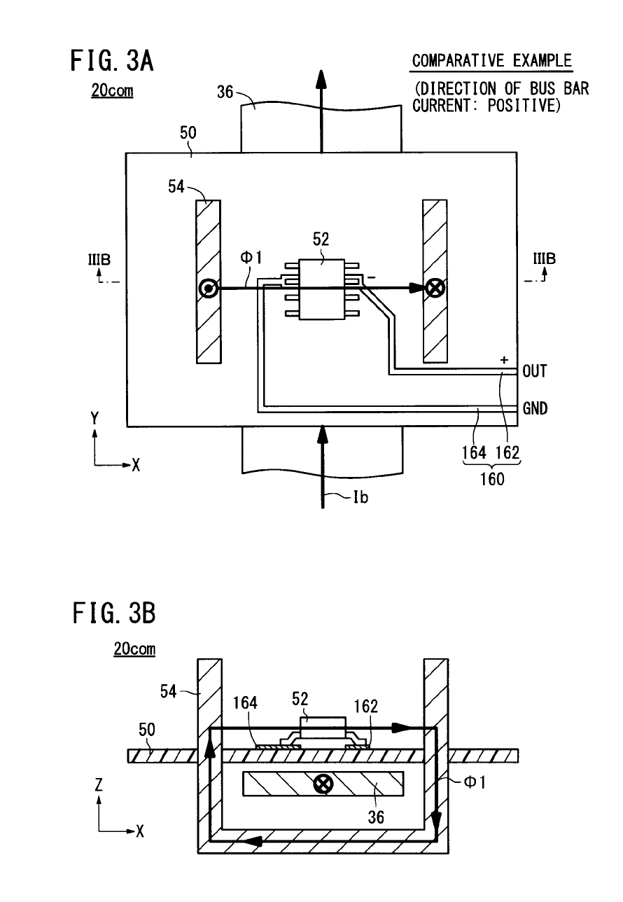

FIG. 3A is a plan view of a coreless current sensor 20com (hereinafter referred to as a “current sensor 20com”), which is free of the turn wire 66 according to a comparative example, and which shows the manner in which the bus bar current Ib flows in an upward direction (hereinafter referred to as a “positive direction”). FIG. 3B is a cross-sectional view taken along line IIIB-IIIB of FIG. 3A. The current sensor 20com includes a printed wire 160 having an output line 162 and a ground line 164, each of which is free of the turn wire 66.

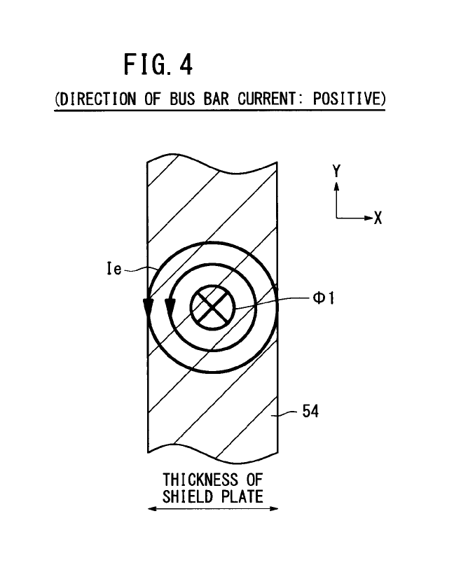

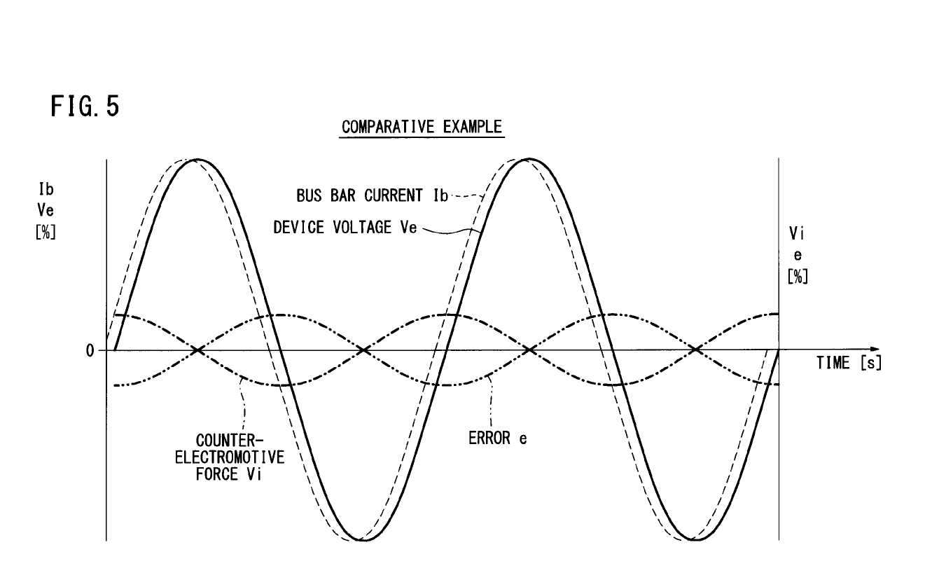

The current sensor 20com operates in the following manner when the positive bus bar current Ib flows in the current sensor 20com.
(a-1) Upon flowing of the positive bus bar current Ib, a magnetic field is generated around the bus bar 36 in a clockwise direction in FIG. 3B, i.e., from the left to the right in FIG. 3A, according to Ampere's right-hand rule, thereby producing a magnetic flux θ1 in the shield plate 54 around the bus bar 36.
(a-2) When the magnetic flux θ1 is produced in the shield plate 54, as shown in FIG. 4, an eddy current Ie is generated in the shield plate 54 in a direction that acts to oppose a change in the magnetic flux θ1.
(a-3) Due to the eddy current Ie generated in the shield plate 54, the magnetic flux θ1 produced in the shield plate 54 suffers a slight phase deviation from the bus bar current Ib. Therefore, the waveform of the output (device voltage Ve) from the magnetic detecting device 52, which detects the magnetic flux θ1, also has a phase deviation (response delay) from the bus bar current Ib (see FIG. 5). As shown in FIG. 5, an error e represents an error that occurs between the bus bar current Ib and the device voltage Ve as a result of the response delay.

As described above, the coreless current sensor 20com according to the comparative example causes a phase delay (response delay) between the waveform of the bus bar current

Ib and the waveform of the device voltage Ve. Bus bar currents Ib in U, V, and W phases, which are detected by the respective coreless current sensors 20com, are required in order to calculate a d-axis current Id and a q-axis current Iq for energizing the motor 12 (see, JP2010-045874A). The phase delay (response delay) between the bus bar current Ib and the device voltage Ve makes it impossible to control the motor 12 accurately, resulting in a reduction in output efficiency of the motor 12. Such a problem is manifested in particular when the rotational speed [rpm] of the motor 12 is high.

### (2-1-2. When the Bus Bar Current Ib Flows in a Negative Direction)

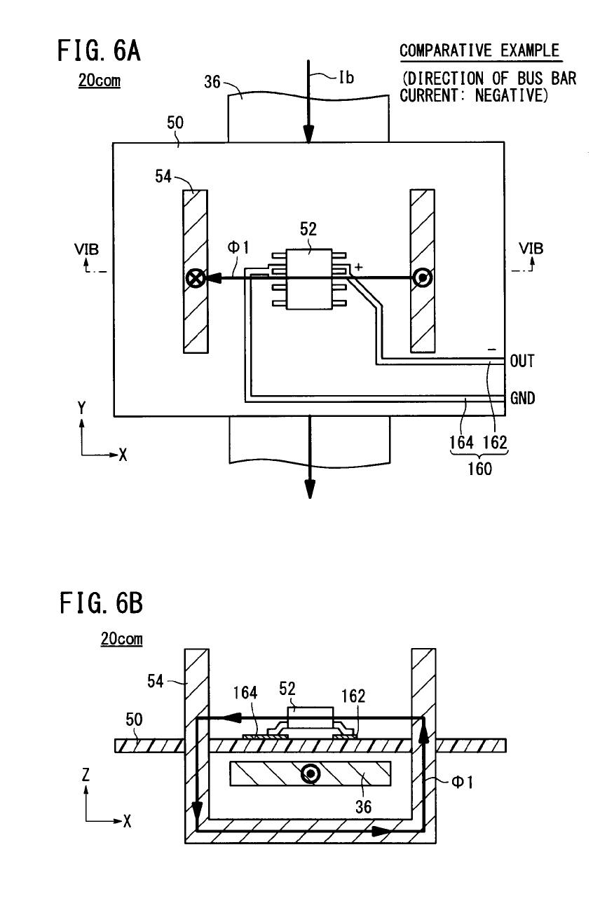

FIGS. 6A and 6B show a magnetic flux θ1, which is produced around the coreless current sensor 20com according to the comparative example, when the bus bar current Ib flows in a downward direction (hereinafter referred to as a “negative direction”) in FIG. 6A.

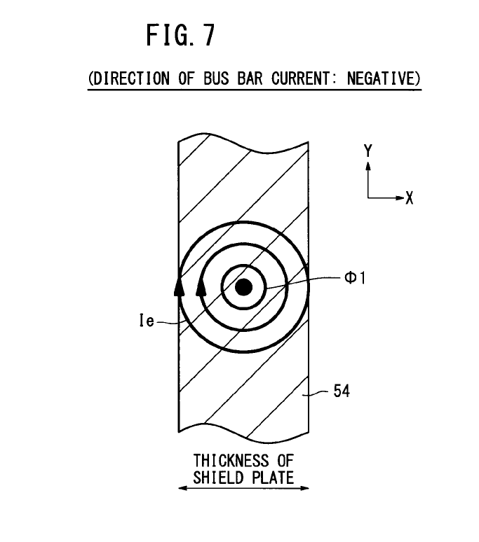

The current sensor 20com operates in the following manner when the negative bus bar current Ib flows in the current sensor 20com.
(b-1) Upon flowing of the negative bus bar current Ib, a magnetic field is generated around the bus bar 36 in a counterclockwise direction in FIG. 6B, i.e., from the right to the left as shown in FIG. 6A, according to Ampere's right-hand rule, thereby producing a magnetic flux θ1 in the shield plate 54 around the bus bar 36.
(b-2) When the magnetic flux θ1 is produced in the shield plate 54, as shown in FIG. 7, an eddy current Ie is generated in the shield plate 54 in a direction that acts to oppose a change in the magnetic flux θ1.
(b-3) Due to the eddy current Ie generated in the shield plate 54, the magnetic flux θ1 produced in the shield plate 54 suffers a slight phase deviation from the bus bar current Ib. Therefore, the waveform of the output (device voltage Ve) from the magnetic detecting device 52, which detects the magnetic flux θ1, also has a phase deviation (response delay) from the bus bar current Ib (see FIG. 5).

As described above, when the negative bus bar current Ib flows in the current sensor 20com, the coreless current sensor 20com also suffers from the same problems as those that occur when the positive bus bar current Ib flows in the current sensor 20com.

### [2-2. In the Presence of the Turn Wire 66]

Operations in the presence of the turn wire 66 will be described below. When the inverter 14 is energized, the directions of currents that flow through the bus bars 36 are switched in succession.

### (2-2-1. When the Bus Bar Current Ib Flows in a Positive Direction)

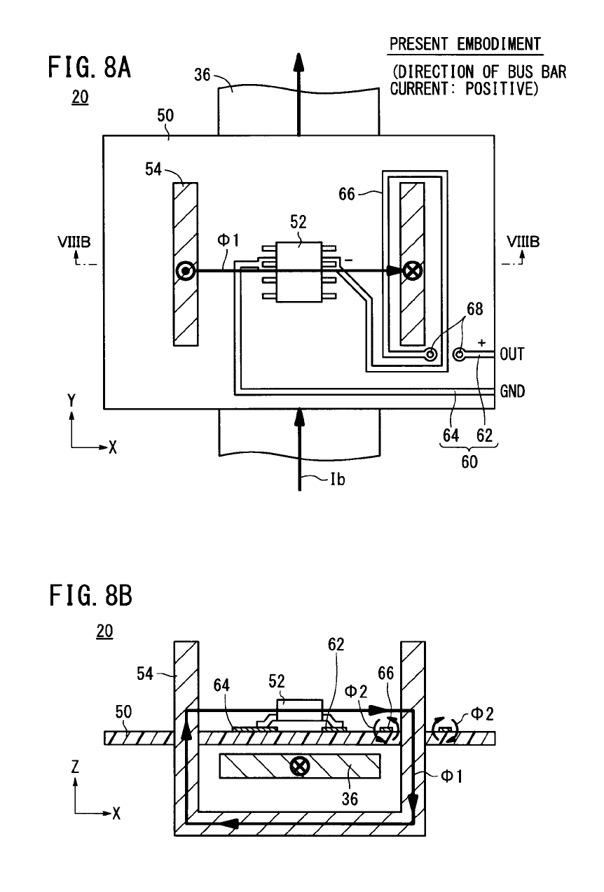

FIGS. 8A and 8B show magnetic fluxes (magnetic fluxes θ1, θ2), which are produced around the current sensor 20 having the turn wire 66, when the bus bar current Ib flows in the positive direction (the upward direction in FIG. 8A).

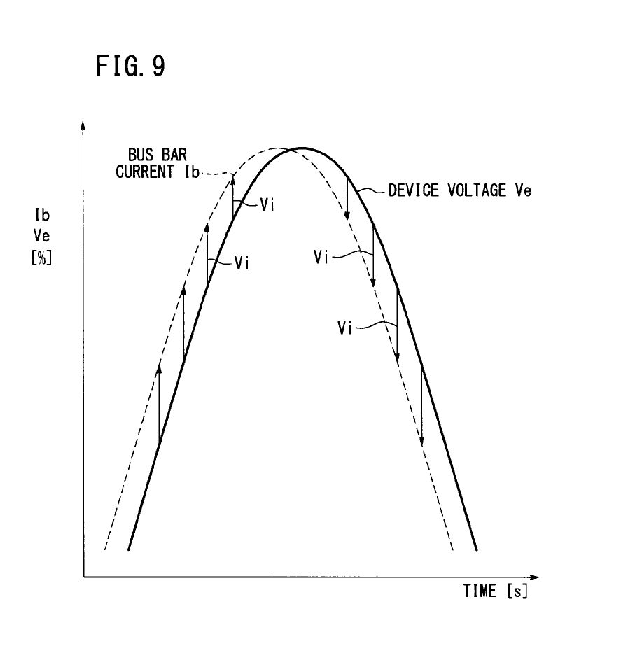

The current sensor 20 operates as follows and offers the following advantages when the positive bus bar current Ib flows in the current sensor 20.
(c-1) Upon flowing of the positive bus bar current Ib, a magnetic field is generated around the bus bar 36 in a clockwise direction in FIG. 8B, i.e., from the left to the right as shown in FIG. 8A, according to Ampere's right-hand rule, thereby producing a magnetic flux θ1 in the shield plate 54 around the bus bar 36.
(c-2) When the magnetic flux θ1 is produced in the shield plate 54, as shown in FIG. 4, an eddy current Ie is generated in the shield plate 54 in a direction that acts to oppose a change in the magnetic flux θ1.
(c-3) Due to the eddy current Ie generated in the shield plate 54, the magnetic flux θ1 produced in the shield plate 54 suffers a slight phase deviation from the bus bar current Ib. Therefore, the waveform of the output (device voltage Ve) from the magnetic detecting device 52, which detects the magnetic flux θ1, also has a phase deviation (response delay) from the bus bar current Ib (see FIG. 5). Operations of the current sensor 20 up to this point are the same as those of the current sensor 20com according to the comparative example.
(c-4) Upon flowing of the positive bus bar current Ib, the voltage (device voltage Ve) on the output line 62 is positive, except at the instant that the polarity of the bus bar current Ib changes from negative to positive. Also, current flows from the ground line 64 toward the output line 62 of the printed wire 60. Therefore, according to Ampere's right-hand rule, a magnetic flux θ2 is produced around the turn wire 66 in a direction opposite to the magnetic flux θ1 in the neighborhood of the shield plate 54 (see FIG. 8B).
(c-5) As the magnetic flux θ1 in the shield plate 54 increases, a counter-electromotive force Vi is generated in the turn wire 66 in a direction (upward direction in FIG. 8B) that acts to oppose the increase in the magnetic flux θ1 (in accordance with Lenz's Law).
(c-6) The direction in which the counter-electromotive force Vi is generated is the same as the direction (upward direction in FIG. 8B) of the magnetic flux θ2 produced in the shield plate 54. As a result, as shown in FIG. 9, the counter-electromotive force Vi is added to the output (device voltage Ve) from the magnetic detecting device 52 that detects the magnetic flux θ1. Thus, the waveform of the device voltage Ve, which is output to the ECU 24, becomes closer in phase to the waveform of the bus bar current Ib, thereby reducing the phase deviation (response delay) between the bus bar current Ib and the device voltage Ve.

As described above, the coreless current sensor 20 according to the present embodiment is capable of reducing a phase deviation (response delay) between the waveform of the bus bar current Ib and the waveform of the device voltage Ve (FIG. 9). The bus bar currents Ib in U, V, and W phases, which are detected by the respective current sensors 20, are required to calculate a d-axis current Id and a q-axis current Iq for energizing the motor 12 (see, JP2010-045874A). Consequently, the reduced phase delay (response delay) between the bus bar current Ib and the device voltage Ve makes it possible to control the motor 12 more accurately, thereby enabling the output efficiency of the motor 12 to be maintained or increased. This advantage is manifested in particular when the rotational speed [rpm] of the motor 12 is high.

### (2-2-2. When the Bus Bar Current Ib Flows in a Negative Direction)

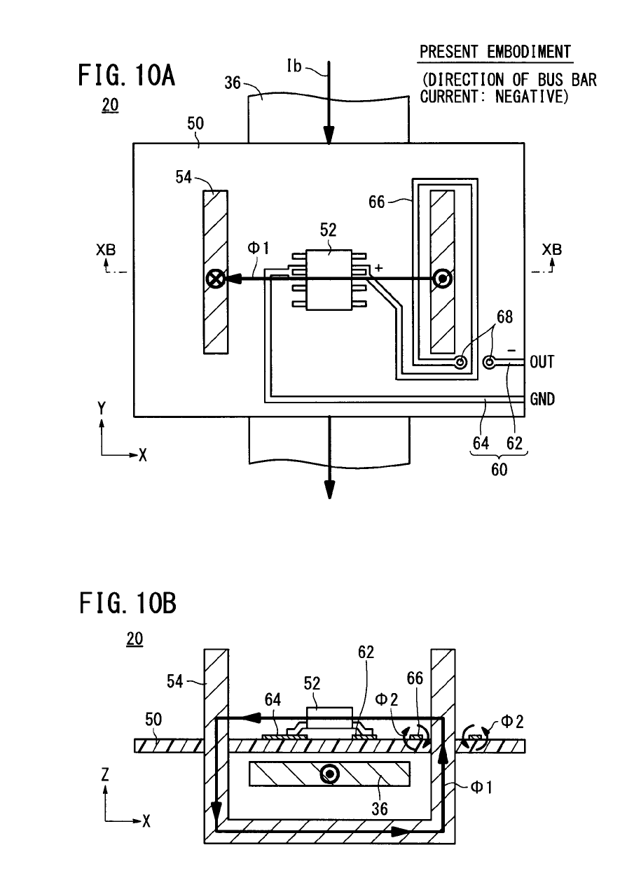

FIGS. 10A and 10B show magnetic fluxes (magnetic fluxes θ1, θ2), which are produced around the current sensor 20 having the turn wire 66, when the bus bar current Ib flows in the negative direction (the downward direction in FIG. 10A).

The current sensor 20 operates as follows and offers the following advantages when the negative bus bar current Ib flows in the current sensor 20.
(d-1) Upon flowing of the negative bus bar current Ib, a magnetic field is generated around the bus bar 36 in a counterclockwise direction in FIG. 10B, i.e., from the right to the left in FIG. 10A, according to Ampere's right-hand rule, thereby producing a magnetic flux θ1 in the shield plate 54 around the bus bar 36.
(d-2) When the magnetic flux θ1 is produced in the shield plate 54, as shown in FIG. 7, an eddy current Ie is generated in the shield plate 54 in a direction that acts to oppose a change in the magnetic flux θ1.
(d-3) Due to the eddy current Ie generated in the shield plate 54, the magnetic flux θ1 produced in the shield plate 54 suffers a slight phase deviation from the bus bar current Ib. Therefore, the waveform of the output (device voltage Ve) from the magnetic detecting device 52, which detects the magnetic flux θ1, also has a phase deviation (response delay) from the bus bar current Ib (see FIG. 5). Operations of the current sensor 20 up to this point are the same as those of the current sensor 20com according to the comparative example.
(d-4) Upon flowing of the negative bus bar current Ib, the voltage (device voltage Ve) on the output line 62 is negative, except at the instant that the polarity of the bus bar current Ib changes from positive to negative. Also, current flows from the output line 62 toward the ground line 64 of the printed wire 60. Therefore, according to Ampere's right-hand rule, a magnetic flux θ2 is produced around the turn wire 66 in a direction opposite to the magnetic flux θ1 in the neighborhood of the shield plate 54 (see 10B).
(d-5) As the magnetic flux θ1 in the shield plate 54 increases, a counter-electromotive force Vi is generated by the turn wire 66 in a direction (downward direction in FIG. 10B) that acts to oppose the increase in the magnetic flux θ1 (in accordance with Lenz's law).
(d-6) The direction in which the counter-electromotive force Vi is generated is the same as the direction (downward direction in FIG. 10B) of the magnetic flux θ2 produced in the shield plate 54. As a result, as shown in FIG. 9, the counter-electromotive force Vi is added to the output (device voltage Ve) from the magnetic detecting device 52 that detects the magnetic flux θ1. Thus, the waveform of the device voltage Ve, which is output to the ECU 24, becomes closer in phase to the waveform of the bus bar current Ib, thereby reducing the phase deviation (response delay) between the bus bar current Ib and the device voltage Ve.

As described above, upon flowing of the negative bus bar current Ib, the coreless current sensor 20 according to the present embodiment offers the same advantages as those that are realized when the positive bus bar current Ib flows.

### [2-3. Number of Turns of the Turn Wire 66]

According to the present embodiment, as described above, the counter-electromotive force Vi is added to the device voltage Ve in order to reduce the phase deviation (response delay) between the bus bar current Ib and the device voltage Ve. The effect of reducing the phase deviation (response delay) can be adjusted depending on the number of turns Nt of the turn wire 66. In FIG. 2A, the number of turns Nt is 1.

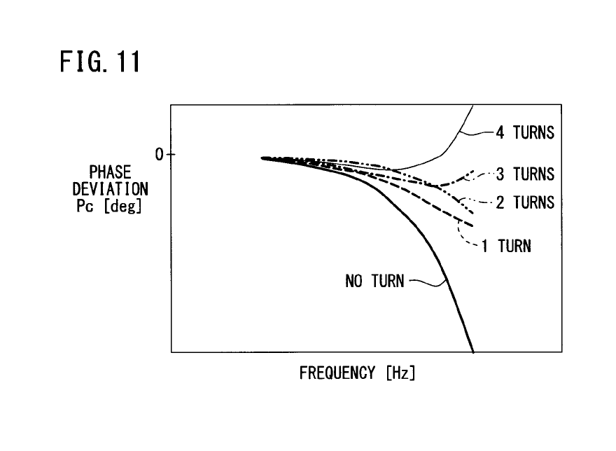

FIG. 11 is a diagram showing by way of example the relationship between the number of turns Nt of the turn wire 66 around the shield plate 54 and phase deviations Pc [deg] of the corrected device voltage Ve. In FIG. 11, if the number of turns Nt is zero, the phase deviation Pc is very large. As the number of turns Nt increases to 1 and 2, the phase deviation Pc becomes smaller. The phase deviation Pc is closest to zero when the number of turns Nt is 3. In the example shown in FIG. 11, therefore, the phase deviation Pc becomes optimum when the number of turns Nt is 3.

### 3. Advantages of the Embodiment

According to the present embodiment, as described above, the counter-electromotive force Vi from the output line 62 is added to the device voltage Ve in order to compensate for the phase deviation (response delay) between the waveform of the bus bar current Ib and the waveform of the device voltage Ve. Consequently, it is possible to suppress the phase deviation (response delay) with a simple arrangement.

### 4. Modifications

The present invention is not limited to the above embodiment, but may incorporate various alternative arrangements based on the disclosure of the present description. For example, the present invention may employ the following arrangements.

[4-1. Objects in which the Invention may be Incorporated]

According to the above embodiment, the coreless current sensor 20 is incorporated in a vehicle 10. However, the coreless current sensor 20 may be incorporated in other objects. For example, the current sensor 20 may be incorporated in various mobile bodies such as electric trains, ships, airplanes, or the like. Alternatively, the current sensor 20 may be incorporated in machine tools or electric products.

According to the above embodiment, the coreless current sensor 20 is used in an AC-based application (e.g., for energizing an AC motor 12). However, the coreless current sensor 20 is not limited to such an application, and may be used in applications for compensating a phase deviation (response delay) between a detected current and an output voltage. For example, the coreless current sensor 20 may be used in DC motors, so as to enable quick switching (from OFF to ON or from ON to OFF) to be detected with a high response.

### [4-2. Shield Plate 54]

According to the above embodiment, the shield plate 54 is of a rectangular shape with one side removed (i.e., a U shape with corners) (see FIGS. 2A and 2B). However, the shield plate 54 is not limited to such a shape, and may be of a curved shape (i.e., a U shape without corners), for example.

According to the above embodiment, the shield plate 54 has been given as an example of a component for producing a response delay in the device voltage Ve from the magnetic detecting device 52. However, another conductor (in particular, a conductor that facilitates generation of eddy currents) may be used to produce such a response delay. If the shield plate 54 is used, the eddy current Ie is proportional to the square of the thickness of the shield plate 54.

### [4-3. Turn Wire 66]

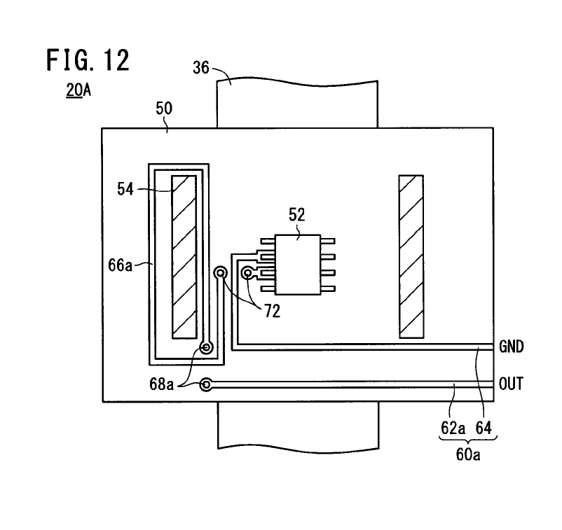

According to the above embodiment, as shown on the right side in FIG. 2A, the turn wire 66 is included in the output line 62 in surrounding relation to the shield plate 54. However, as shown on the left side in FIG. 12, a coreless current sensor 20A (first modification) shown in FIG. 12 has a turn wire 66a included in an output line 62a of a printed wire 60a, so as to be coiled around the shield plate 54. In FIG. 12, using the through holes 72, the output line 62a is kept out of contact with the ground line 64, and using the through holes 68a, the output line 62a is prevented from having overlapping portions.

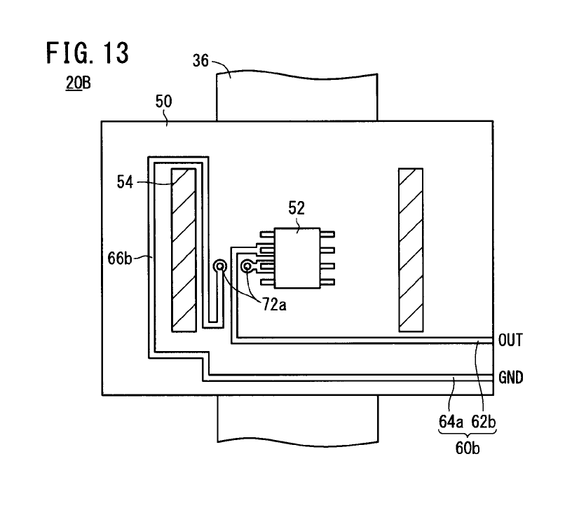

According to the above embodiment and the first modification shown in FIG. 12, the turn wires 66, 66a are included within the output lines 62, 62a. However, a coreless current sensor 20B (second modification) shown in FIG. 13 does not have a turn wire included within the output line 62b of the printed wire 60b, but instead, the ground line 64a is included within the turn wire 66b. As shown in FIG. 12, using the through holes 72a, the ground line 64a is kept out of contact with the output line 62b.

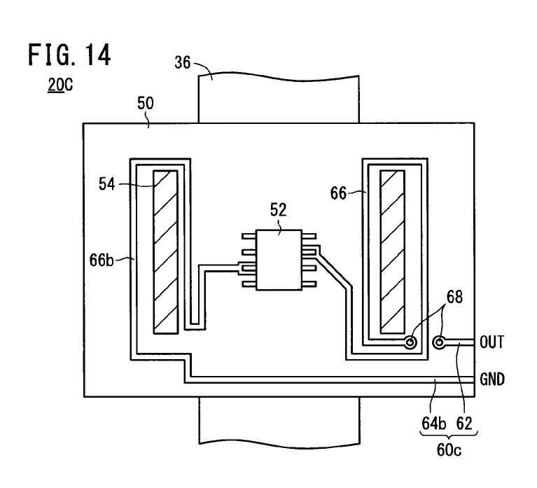

Alternatively, a coreless current sensor 20C (third modification) shown in FIG. 14 has a turn wire 66 in an output line 62 of a printed wire 60c, and has a turn wire 66b in a ground line 64b.

According to the above embodiment as well as the first through third modifications, on the printed circuit board 50 that lies parallel to the bus bar 36, in both plan and cross-sectional views, the turn wire 66 is disposed on one or both of the right side or the left side of the magnetic detecting device 52. However, the turn wire 66 is not limited to such a position. If the printed circuit board 50 is of a three-dimensional pattern, for example, the turn wire 66 may be positioned on the upper side or the lower side, or on both upper and lower sides, of the magnetic detecting device 52, as viewed in cross-section.

### [4-4. Other Applications]

According to the above embodiment, the turn wire 66 is used to reduce a phase deviation (response delay) between the waveform of the bus bar current Ib and the waveform of the device voltage Ve. However, the turn wire 66 also is suitable for an application of increasing the phase deviation (response delay) between the waveform of the bus bar current Ib and the waveform of the device voltage Ve, e.g., an application for delaying the output of the magnetic detecting device 52 in synchronism with another output. In such an application, the turn wires 66, 66a, 66b should be coiled in an opposite direction around the shield plate 54.

1. A coreless current sensor structure comprising:
a magnetic detecting device for detecting a magnetic flux produced from a current path and converting the detected magnetic flux into a voltage;
a shield plate disposed around the magnetic detecting device for blocking an external magnetic flux toward the magnetic detecting device;
wherein an output voltage converted from a detected magnetic flux by the magnetic detecting device is converted into a current in order to detect a current flowing through the current path; and
a connection line connected to terminals of the magnetic detecting device and including a coiled portion surrounding the shield plate;
wherein the current is calculated based on a voltage across the magnetic detecting device.

2. The coreless current sensor structure according to claim 1, wherein the coiled portion is disposed around the shield plate such that a response delay in the output voltage from the magnetic detecting device, which is caused with respect to a change that occurs in the current flowing through the current path due to a delay of a change in a magnetic flux applied to the shield plate with respect to the change in the current, is compensated for by a counter-electromotive force generated in the coiled portion depending on the change in the magnetic flux applied to the shield plate.

3. The coreless current sensor structure according to claim 1, wherein the connection line, which includes the coiled portion further includes an output line on which voltage changes depending on the voltage conversion; and
the coiled portion is coiled counterclockwise around a first specific region of the shield plate from a side of the output line proximate the magnetic detecting device and toward an output end of the output line, as the first specific region of the shield plate is viewed in a direction of the magnetic flux at the first specific region, when the magnetic detecting device outputs a positive voltage based on the generated magnetic flux produced from the current path.

4. The coreless current sensor structure according to claim 1, wherein the connection line, which includes the coiled portion, further includes a ground line; and
the coiled portion is coiled clockwise around a second specific region of the shield plate from a side of the ground line proximate the magnetic detecting device and toward an output end of the ground line, as the second specific region of the shield plate is viewed in a direction of the magnetic flux at the second specific region, when the magnetic detecting device outputs a positive voltage based on the generated magnetic flux produced from the current path.

5. A coreless current sensor comprising:
a magnetic detecting device for detecting a magnetic flux produced from a current path and converting the detected magnetic flux into a voltage;
a conductor disposed around the magnetic detecting device; and
a wire for outputting an output voltage from the magnetic detecting device to an external circuit, the wire including a coiled portion disposed around the conductor;
wherein the conductor is placed in a position in which the conductor generates an eddy current due to a magnetic flux produced from the current path, thereby causing a delay of a change in the magnetic flux detected by the magnetic detecting device with respect to a change in a current flowing through the current path; and
the coiled portion of the wire is disposed such that a response delay in the output voltage from the magnetic detecting device, which is caused with respect to the change that occurs in the current flowing through the current path due to a delay of a change in the magnetic flux with respect to the change in the current, is compensated for by a counter-electromotive force generated in the coiled portion in a direction to oppose the change in the magnetic flux applied to the conductor.

6. A current detecting method to be carried out using a coreless current sensor including a magnetic detecting device for detecting a magnetic flux produced from a current path and converting the detected magnetic flux into a voltage, a conductor disposed around the magnetic detecting device, and a wire for outputting an output voltage from the magnetic detecting device to an external circuit, the wire including a coiled portion disposed around the conductor, comprising the steps of:
placing the conductor in a position in which the conductor generates an eddy current due to a magnetic flux produced from the current path, thereby causing a delay of a change in the magnetic flux detected by the magnetic detecting device with respect to a change in a current flowing through the current path;
generating a counter-electromotive force in the coiled portion in a direction to oppose the change in the magnetic flux applied to the conductor; and
compensating for a phase deviation between a waveform of the current flowing through the current path and a waveform of an output from the magnetic detecting device by using the counter-electromotive force for the conductor, the phase deviation being caused due to the delay of the change in the magnetic flux with respect to the change in the current.
